(19) United States
(12) Patent Application Publication
(10) Pub. No.: US 2014/0313668 A1
(43) Pub. Date: Oct. 23, 2014

(54) PROTECTIVE DEVICE

(71) Applicant: FOXCONN TECHNOLOGY CO., LTD., New Taipei (TW)

(72) Inventors: WEI-HANG HSU, New Taipei (TW); JUI-WEN HUNG, New Taipei (TW)

(73) Assignee: FOXCONN TECHNOLOGY CO., LTD., New Taipei (TW)

(21) Appl. No.: 13/873,177

(22) Filed: Apr. 29, 2013

(30) Foreign Application Priority Data
Apr. 19, 2013 (TW) 102113878

(51) Int. Cl. H05K 7/20

(52) U.S. Cl. CPC H05K 7/20509
USPC 361/697; 361/748; 361/709; 361/700

(57) ABSTRACT

An exemplary protective device is for protecting an electronic component mounted on a printed circuit board. The protective device includes a protective board covering the electronic component, and a hard carbon film coated on an outer periphery of the protective board. The protective board is made of anti-EMI materials.

### BACKGROUND

1. Technical Field

The disclosure relates to a protective device adapted for electronic components, more particularly, relates to an improved protective device having good heat dissipating and anti-EMI performance.

2. Description of Related Art

In use of a computer, electronic components, such as CPU or GPU, on high-frequency circuits produce electromagnetic waves. Such electromagnetic waves are liable to cause EMI (electromagnetic interference) in other nearby electronic devices. In particular, sensitive electronic devices near the computer may malfunction. Generally, a protective device covering the electronic component is provided for preventing EMI.

However, heat generated from the electronic components is often increased. The protective device covering the electronic components would cause the operational temperature of the electronic components to increase. It is not properly satisfy the requirement of transferring the heat from the electronic components.

What is needed, therefore, is an improved protective device which overcomes the above described shortcomings.

### BRIEF DESCRIPTION OF THE DRAWINGS

FIG. 1 is an assembled, isometric view of a protective device in accordance with an embodiment of the disclosure, with a printed circuit board and an electronic component positioned mounted on the printed circuit board.

FIG. 2 is an inverted view of the protective device of FIG. 1, with the electronic component.

FIG. 3 is an exploded view of the protective device of FIG. 1.

FIG. 4 is a cross-sectional view of FIG. 2, taken along line IV-IV thereof.

### DETAILED DESCRIPTION

An embodiment of a protective device in accordance with the present disclosure will now be described in detail below and with reference to the drawings.

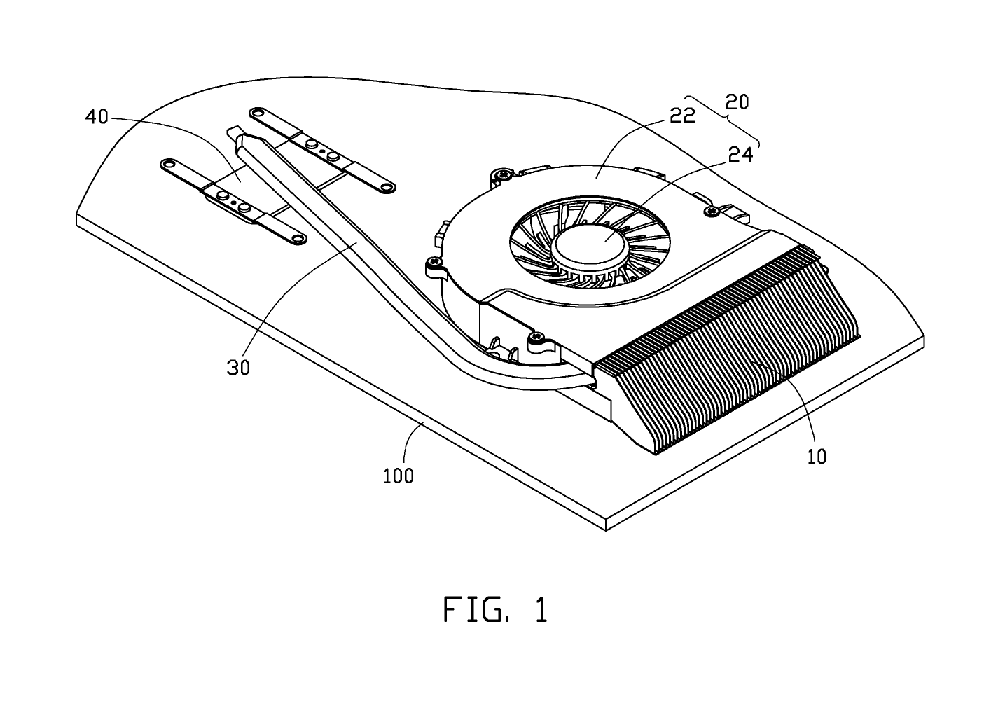

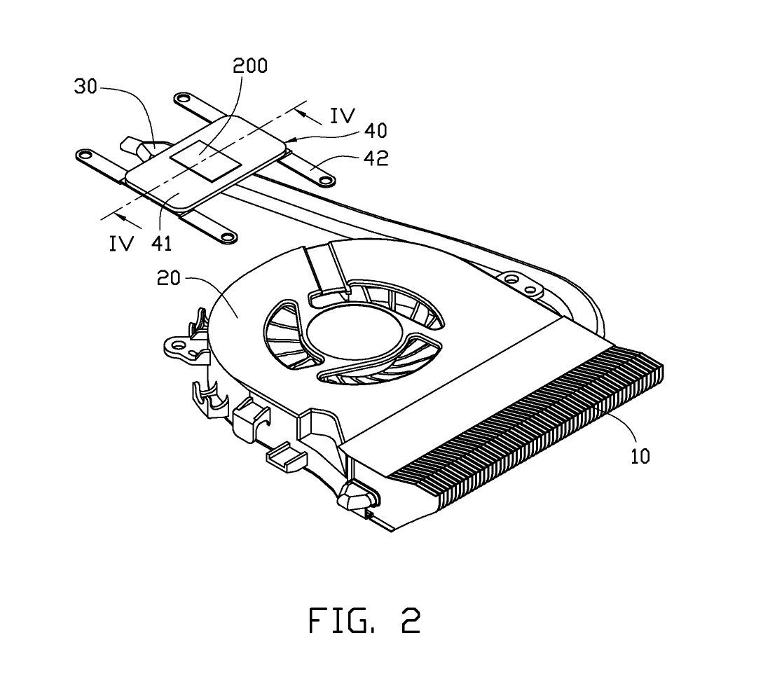

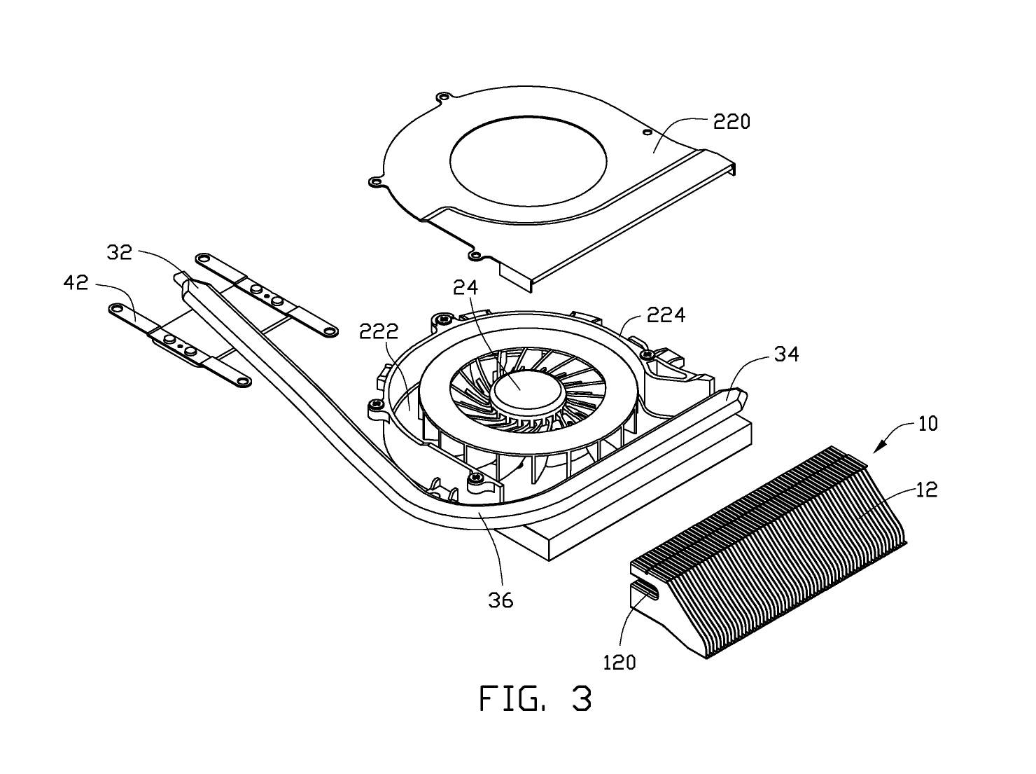

Referring to FIGS. 1-3, a protective device in accordance with an exemplary embodiment of the disclosure is illustrated. The protective device is adapted for protecting an electronic component 200 such as a CPU (central processing unit) arranged on a printed circuit board 100. The protective device includes a fin unit 10, a centrifugal fan 20 located adjacent to the fin unit 10, a heat pipe 30 thermally connecting to the fin unit 10, and a protective board 40 covering the electronic component 200. The heat pipe 30 connects the protective board 40 to the fin unit 10.

The fin unit 10 includes a plurality of fins 12, each of which consists of an upright sheet body and a pair of flanges bent horizontally from a top and a bottom of the sheet body and engaging with the sheet body of an adjacent fin 12. Every two adjacent fins 12 define a passage the two adjacent fins 12 for allowing airflow to pass through. An elongated receiving groove 120 is defined at a front side of the fin unit 10 and faces the centrifugal fan 20, for accommodating an end of the heat pipe 30. The receiving groove 120 extends transversely and perpendicularly through the fin unit 10 and is located at a left side of the fin unit 10.

The centrifugal fan 20 includes a housing 22 engaging with the fin unit 10 and an impeller 24 rotatably located in the housing 22. The housing 22 comprises a top plate 220, a bottom plate 222 located opposite to the top plate 220 and a volute sidewall 224 extending upwardly from an outer periphery of the bottom plate 222 and fixed to the top plate 220. Each of the top plate 220 and the bottom plate 222 defines a through hole at a center for functioning as an air inlet for the centrifugal fan 20. The top plate 220, the bottom plate 222, and the sidewall 224 cooperatively define a receiving space for receiving the impeller 24. The sidewall 224 defines a rectangular air outlet at a right lateral side of the housing 22. The fin unit 10 is partly received in the air outlet of the housing 22, and the passages of the fin unit 10 directly communicate with the air outlet.

The heat pipe 30 includes a straight evaporating section 32, a straight condensing section 34 and a bended connecting section 36 interconnecting the evaporating section 32 and the condensing section 34. The evaporating section 32 is thermally attached to the protective board 40. The condensing section 34 is thermally received in the receiving groove 120 of the fin unit 10. A bottom face and a top face of the heat pipe 30 are planar.

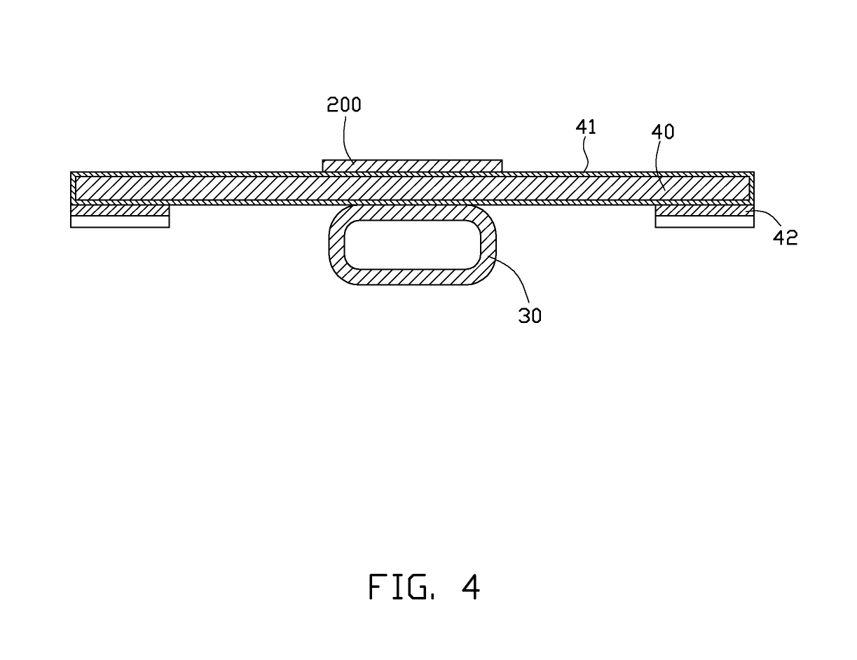

Referring to FIG. 4 also, the protective board 40 is an approximately rectangular plate, and made of materials with good anti-EMI performance, such as tinplate, Be—Cu alloy, or weaving wires. Alternatively, the protective board 40 could have a configuration like a shell. The protective board 40 is located between the evaporating section 32 of the heat pipe 30 and the electronic component 200.

The protective device further includes a hard carbon film 41 coated on an outer periphery of the protective board 40. In this embodiment, the hard carbon film 41 totally covers the protective board 40. Alternatively, the hard carbon film 41 could only partially cover the protective board 40. The hard carbon film 41 is selected from diamond carbon film or diamond-like carbon film. The hard carbon film 41 is coated on the protective board 40 in a manner of evaporation deposition, PECVD (Plasma-Enhanced Chemical Vapor Deposition), or magnetron sputtering. A thickness of the hard carbon film 41 is at least 0.1 um. The evaporating section 32 of the heat pipe 30 is attached on the hard carbon film 41 coated on a top face of the protective board 40. The hard carbon film 41 coated on a bottom face of the protective board 40 is correspondingly attached on the electronic component 200. Two mounting members 42 are further provided to the protective board 40, for fixing the protective board 40 to the printed circuit board 100. The two mounting members 42 are located at two opposite sides of the protective board 40, respectively.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A protective device for protecting an electronic component mounted on a printed circuit board, the protective device comprising:
a protective board covering the electronic component, the protective board being made of anti-EMI materials; and
a hard carbon film coated on an outer periphery of the protective board.

2. The protective device of claim 1, wherein the hard carbon film is diamond carbon film or diamond-like carbon film.

3. The protective device of claim 1, wherein a thickness of the hard carbon film is at least 0.1 um.

4. The protective device of claim 1, wherein the hard carbon film is coated on the protective board in a manner of evaporation deposition, PECVD, or magnetron sputtering.

5. The protective device of claim 1, wherein the hard carbon film totally covers the protective board.

6. The protective device of claim 1, wherein the hard carbon film partially covers the protective board.

7. The protective device of claim 1, further comprising a fin unit thermally connecting to the protective board, the fin unit comprising a plurality of fins.

8. The protective device of claim 7, further comprising a centrifugal fan located adjacent to the fin unit, wherein the centrifugal fan comprises a housing and an impeller rotatably located in the housing, and an air outlet is defined at a right lateral side of the housing, and the fin unit is partly received in the air outlet.

9. The protective device of claim 7, further comprising a heat pipe thermally connecting the fin unit and the protective board.

10. The protective device of claim 9, wherein the heat pipe comprises an evaporating section attached to the protective board, a condensing section attached to the fin unit, and a connecting section interconnecting the evaporating section and the condensing section.

11. The protective device of claim 9, wherein the protective board is located between the evaporating section of the heat pipe and the electronic component.

12. The protective device of claim 11, wherein the evaporating section of the heat pipe is attached on the hard carbon film coated on a top face of the protective board.

13. The protective device of claim 11, wherein the hard carbon film coated on a bottom face of the protective board is attached on the electronic component.

14. The protective device of claim 7, wherein an elongated receiving groove is defined at a lateral side of the fin unit, for accommodating the condensing section of the heat pipe.

15. The protective device of claim 1, wherein the protective board is made of tinplate, Be—Cu alloy, or weaving wires.
